(19) United States
(12) Patent Application Publication
(10) Pub. No.: US 2026/0029205 A1
(43) Pub. Date: Jan. 29, 2026

(54) LIQUID COLLECTING ASSEMBLY AND TERMINAL DEVICE

(71) Applicant: Fulian Precision Electronics (Tianjin) Co., LTD., Tianjin (CN)

(72) Inventors: WEN-LING CHIANG, New Taipei (TW); HSIAO-HSUAN CHANG, New Taipei (TW)

(21) Appl. No.: 18/963,632

(22) Filed: Nov. 28, 2024

(30) Foreign Application Priority Data
Jul. 29, 2024 (CN) 202411019471.7

(51) Int. Cl. F28F 25/00

(52) U.S. Cl. CPC F28F 25/00; F28F 2025/005

(57) ABSTRACT

A liquid collecting assembly includes a first structural member and a second structural member. The first structural member includes a first receiving portion and a first latching portion. The first receiving portion defines a first through slot. A first receiving groove is formed between the first latching portion and the first receiving portion. The second structural member defines a second through slot. The first structural member is slidably connected to the second structural member. The first receiving portion can accommodate in the second through slot, and the second structural member can accommodate in the first receiving groove.

### FIELD

The subject matter herein generally relates to terminals, and more particularly, to a liquid collecting assembly and a terminal device.

### BACKGROUND

A terminal device includes a liquid cooler to dissipate heat generated by the terminal device. The terminal device further includes a pipeline and a water collecting member. The pipeline is connected to the liquid cooler and passes through the water collecting member. The water collecting member can collect a liquid leaked from the pipeline.

The water collecting member needs to adapt to a length of the terminal device. The length of the water collecting member needs to be changed when being installed to terminal devices with different lengths or when an installing position of the water collecting member in the terminal device is changed. Thus, the compatibility of the water collecting member is poor, which increases the production cost. Therefore, there is a room for improvement in the art.

### BRIEF DESCRIPTION OF THE DRAWINGS

Implementations of the present technology will now be described, by way of example only, with reference to the attached figures.

FIG. 1 is an exploded view of a terminal device according to an embodiment of the present disclosure.

FIG. 2 is a diagram showing a liquid collecting assembly of FIG. 1 being in an extended state.

FIG. 3 is a diagram showing the liquid collecting assembly of FIG. 1 being in a retracted state.

FIG. 4 is similar to the FIG. 3, but showing the liquid collecting assembly from another angle.

FIG. 5 is a diagram showing the liquid collecting assembly of FIG. 1 in different states.

FIG. 6 is an exploded view of the liquid collecting assembly of FIG. 2.

FIG. 7 is a diagram showing a first structural member of the liquid collecting assembly of FIG. 6.

FIG. 8 is an exploded view showing area I of FIG. 7.

FIG. 9 is a diagram showing a second structural member of the liquid collecting assembly of FIG. 6.

FIG. 10 is a diagram showing a connecting member of the liquid collecting assembly of FIG. 6.

FIG. 11 is an exploded view showing area II of the connecting member of FIG. 10.

FIG. 12 is a cross-sectional view along line A-A of the liquid collecting assembly FIG. 3.

FIG. 13 is a cross-sectional view along line B-B the liquid collecting assembly of FIG. 3.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

Some embodiments of the present disclosure will be described in detail with reference to the drawings. If no conflict, the following embodiments and features in the embodiments can be combined with each other.

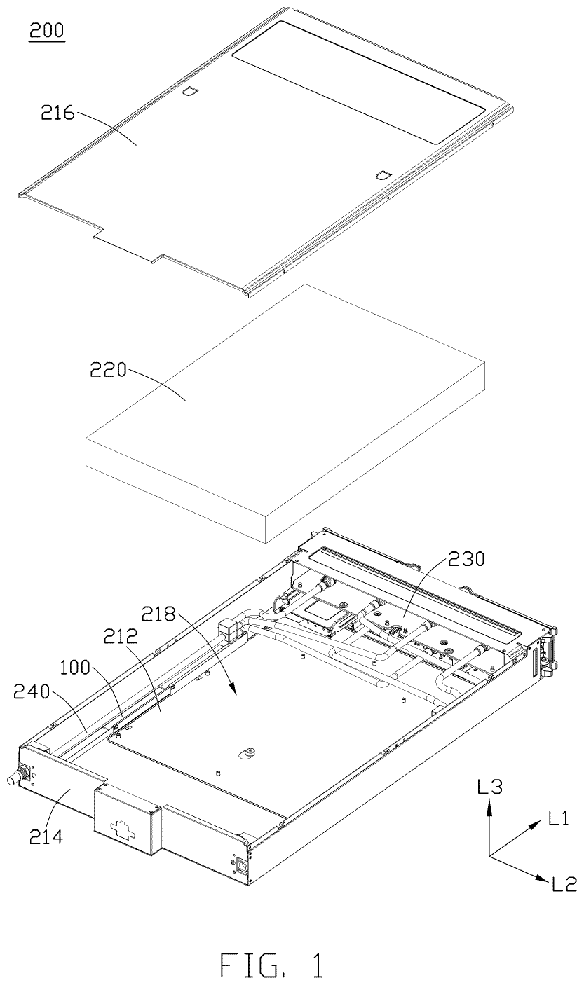

Referring to FIG. 1, a terminal device 200 is provided according to an embodiment of the present disclosure. The terminal device 200 can be a product that generates heat during operation, such as a server, a desktop computer, a laptop computer, or a television. The terminal device 200 shown in FIG. 1 is a server.

The terminal device 200 includes a housing 210, a heat-generating body 220, a liquid cooler 230, a pipeline 240, and a liquid collecting assembly 100. In the embodiment, the heat-generating body 220 is a main component of the server. The heat-generating body 220, the liquid cooler 230, the pipeline 240, and the liquid collecting assembly 100 are accommodated in the housing 210. The liquid cooler 230 is disposed on an end of the heat-generating body 220. The pipeline 240 is connected to the liquid cooler 230. The pipeline 240 is disposed in the liquid collecting assembly 100.

The liquid cooler 230 contains a working medium (not shown), and the working medium can undergo phase changes to rapidly dissipate the heat generated during an operation of the heat-generating body 220, thereby allowing the heat-generating body 220 to operate at an appropriate temperature. The liquid collecting assembly 100 can collect the working medium leaked from the pipeline 240 and discharge the working medium through one end of the liquid collecting assembly 100, thereby preventing leakage of the working medium into other areas of the terminal device 200. The working medium can be water.

The housing 210 includes a bottom wall 212, four sidewalls 214, and a cover plate 216. The four sidewalls 214 are connected end-to-end and surround the bottom wall 212. The bottom wall 212 and the cover plate 216 are disposed on opposite sides of the four sidewalls 214. The bottom wall 212, the four sidewalls 214, and the cover plate 216 cooperatively form a receiving cavity 218. The heat-generating body 220, the liquid cooler 230, the pipeline 240, and the liquid collecting assembly 100 are accommodated in the receiving cavity 218.

The heat-generating body 220 is approximately cuboid. The heat-generating body 220 is disposed on the bottom wall 212. The heat-generating body 220 is spaced apart from each sidewall 214. Directions corresponding to a length, a width, and a height of the heat-generating body 220 are defined as a first direction L1, a second direction L2, and a third direction L3, respectively.

The liquid cooler 230 and the heat-generating body 220 are disposed along the first direction L1. In the embodiment, the terminal device 200 includes two liquid collecting assemblies 100. The two liquid collecting assemblies 100 are disposed on opposite sides of the heat-generating body 220. The two liquid collecting assemblies 100 are disposed along the second direction L2. The two liquid collecting assemblies 100 are disposed close to the sidewalls 214 and are fixed to either the bottom wall 212 or the sidewalls 214.

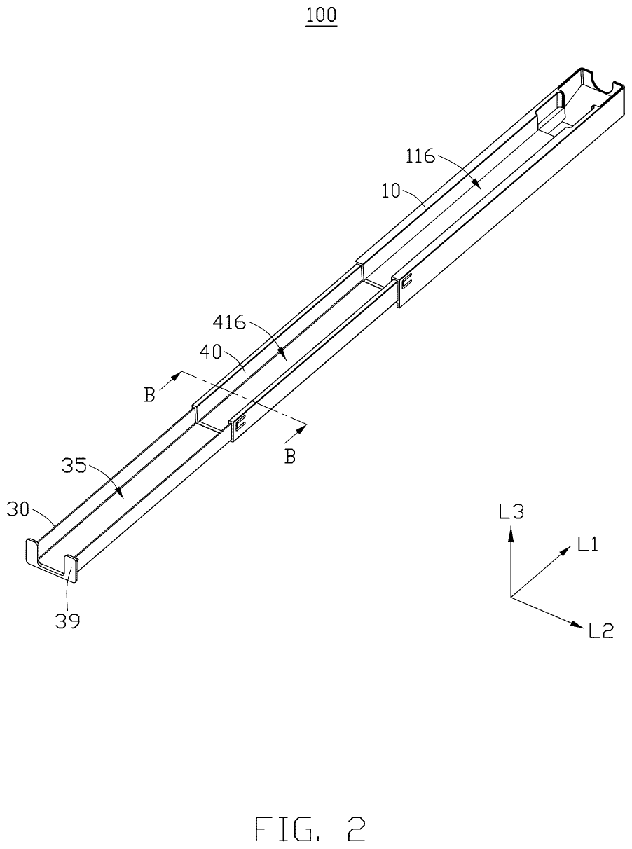

Referring to FIGS. 2, 3, 4, and 5, each liquid collecting assembly 100 includes a first structural member 10, a second structural member 30, and at least one connecting member 40. The connecting member 40 is disposed between the first structural member 10 and the second structural member 30. The connecting member 40 is connected to the first structural member 10 and the second structural member 30. The first structural member 10 is slidably connected to the connecting member 40, and the connecting member 40 is slidably connected to the second structural member 30.

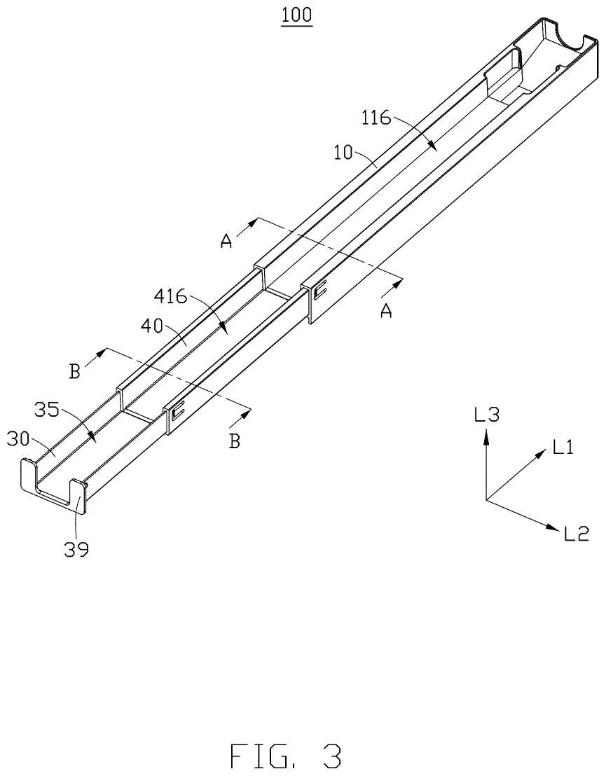

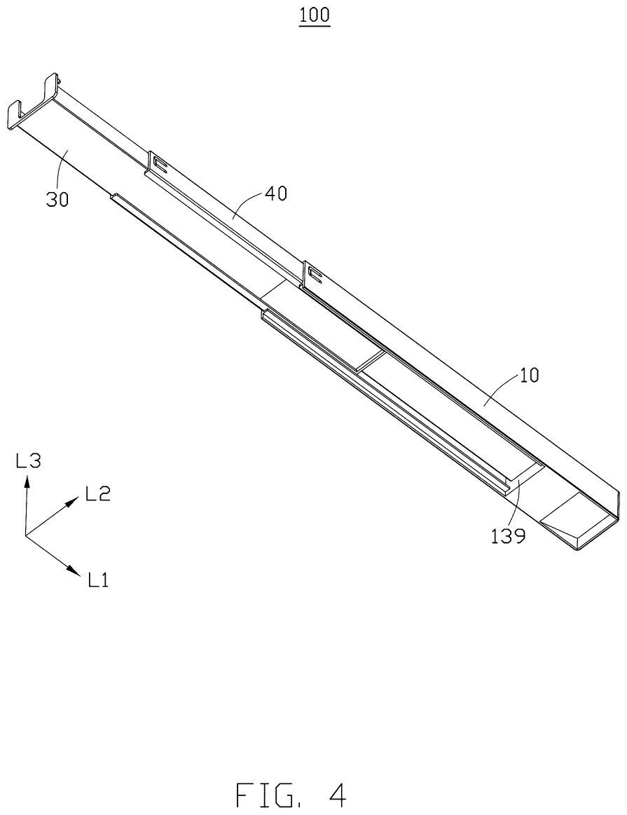

Referring to FIG. 2, when the liquid collecting assembly 100 is in an extended state, at least a portion of the second structural member 30 protrudes from an end of the connecting member 40, and at least a portion of the connecting member 40 protrudes from an end of the first structural member 10. An overall length of the liquid collecting assembly 100 along the first direction L1 is approximately a sum of lengths of the first structural member 10, the connecting member 40, and the second structural member 30. Referring to FIGS. 3 and 4, when the liquid collecting assembly 100 is in a retracted state, at least a portion of the second structural member 30 is accommodated in the connecting member 40, and at least a portion of the connecting member 40 is accommodated in the first structural member 10. The overall length of the liquid collecting assembly 100 along the first direction L1 is approximately the length of the first structural member 10.

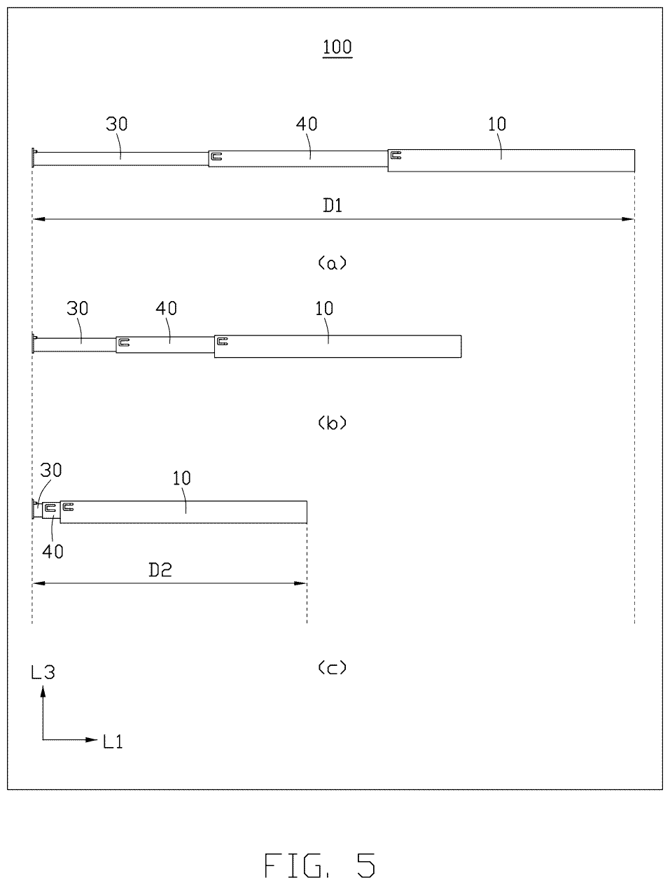

Referring to FIG. 5, the extended state of the liquid collecting assembly 100 is shown in (a) of FIG. 5, and the retracted state of the liquid collecting assembly 100 includes an intermediate state (as shown in (b) of FIG. 5) and a retracted state (as shown in (c) of FIG.

5). The liquid collecting assembly 100 can have a maximum length D1 and a minimum length D2, and can vary between the maximum length D1 and the minimum length D2. In one embodiment, the maximum length D1 of the liquid collecting assembly 100 in the extended state is 522.5 mm, and the minimum length D2 of the liquid collecting assembly 100 in the retracted state is 216.00 mm.

The liquid collecting assembly 100 has an adjustable length. During an installing process of the liquid collecting assembly 100, the overall length of the liquid collecting assembly 100 can be adjusted according to an actual arrangement of components in the terminal device 200 to adapted to different sizes of terminal device 200, thereby reducing production costs and improving a compatibility of the liquid collecting assembly 100.

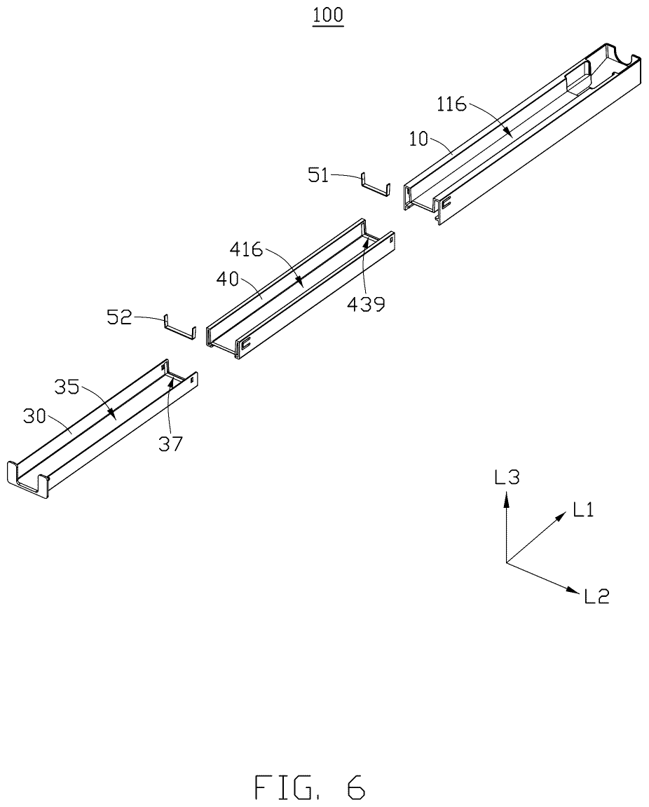

Referring to FIGS. 6, 7, and 8, the first structural member 10 may include a first receiving portion 11 and two first latching portions 13. The first receiving portion 11 defines a first through slot 116. A first receiving groove 137 is defined between one first latching portion 13 and the first receiving portion 11.

The first receiving portion 11 may include a first bottom plate 112 and two first side plates 114. The first bottom plate 112 extends along the first direction L1, and the two first side plates 114 are disposed along the second direction L2 and disposed on two sides of the first bottom plate 112. The first bottom plate 112 and the two first side plates 114 cooperatively form the first through slot 116. Each first latching portion 13 includes a first connecting plate 131 and a second side plate 133. The first connecting plate 131 is connected to the first side plate 114 and the second side plate 133. The first side plate 114 is spaced apart from the second side plate 133. The first side plate 114, the first connecting plate 131, and the second side plate 133 cooperatively form the first receiving groove 137. An opening direction of the first through slot 116 and an opening direction of the first receiving groove 137 are opposite to each other.

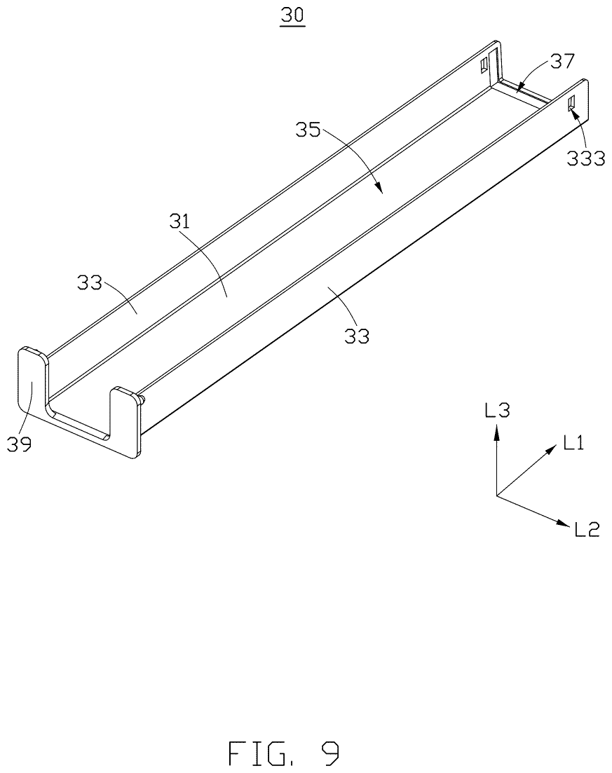

Referring to FIGS. 6 and 9, the second structural member 30 defines a second through slot 35, the second structural member 30 includes a second bottom plate 31 and two third side plates 33. The second bottom plate 31 extends along the first direction L1, and the two third side plates 33 are disposed along the second direction L2 and disposed on two sides of the second bottom plate 31. The second bottom plate 31 and the two third side plates 33 cooperatively form the second through slot 35.

Referring to FIGS. 6, 8, 10, and 11, in the embodiment, the liquid collecting assembly 100 includes one connecting member 40. The connecting member 40 may include a second receiving portion 41 and two second latching portions 43. The second receiving portion 41 defines a third through slot 416, and a second receiving groove 437 is defined between one second latching portion 43 and the second receiving portion 41.

The second receiving portion 41 includes a third bottom plate 412 and two fourth side plates 414. The third bottom plate 412 extends along the first direction L1, and the two fourth side plates 414 are disposed along the second direction L2 and disposed on two sides of the third bottom plate 412. The third bottom plate 412 and the two fourth side plates 414 cooperatively form the third through slot 416. Each second latching portion 43 includes a second connecting plate 431 and a fifth side plate 433. The second connecting plate 431 is connected to one of the fourth side plates 414 and the fifth side plate 433. The fourth side plate 414 is spaced apart from the fifth side plate 433. The fourth side plate 414, the second connecting plate 431, and the fifth side plate 433 cooperatively form the second receiving groove 437. An opening direction of the third through slot 416 and an opening direction of the second receiving groove 437 are opposite to each other. The connecting member 40 is generally similar to the first structural member 10.

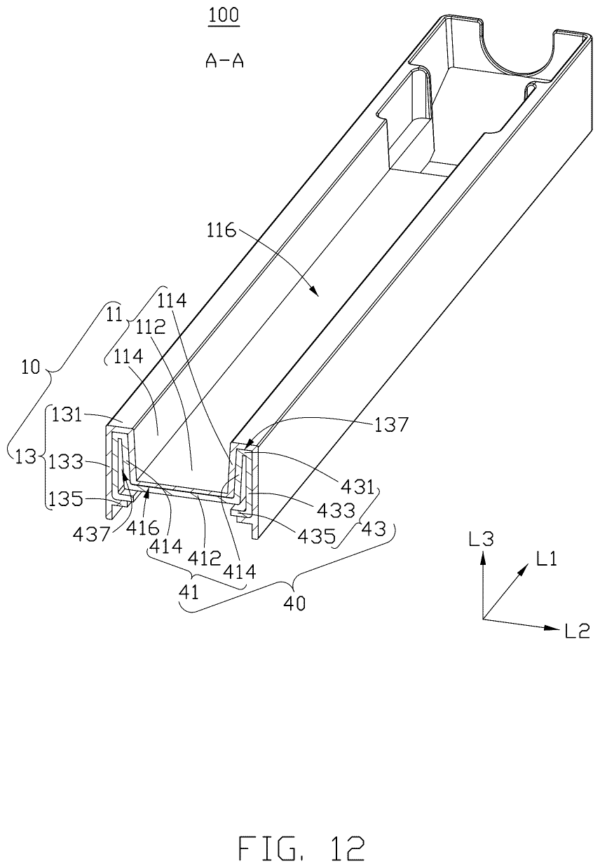

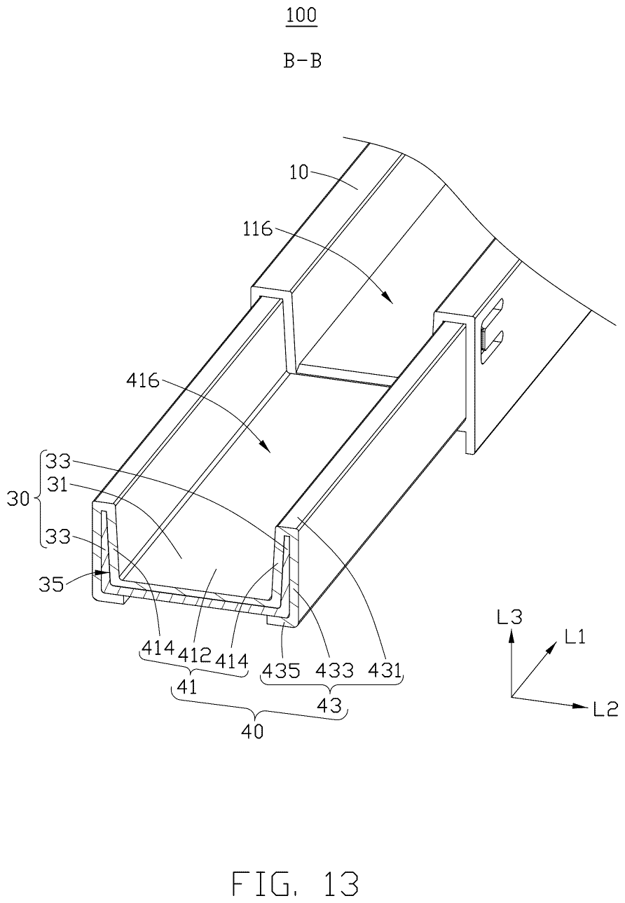

The first through slot 116 of the first structural member 10, the third through slot 416 of the connecting member 40, and the second through slot 35 of the second structural member 30 can accommodate the pipeline 240. The first structural member 10 is slidably connected to the connecting member 40, and the connecting member 40 is slidably connected to the second structural member 30. Referring to FIG. 12, when the first structural member 10 and the connecting member 40 are in the retracted state, the first bottom plate 112 and the two first side plates 114 of the first receiving portion 11 are accommodated in the third through slot 416, and the second receiving portion 41 and the fourth side plates 414 are accommodated in the first receiving groove 137. Referring to FIG. 13, when the connecting member 40 and the second structural member 30 are in the retracted state, the third bottom plate 412 and the two fourth side plates 414 of the second receiving portion 41 are accommodated in the second through slot 35, and the two third side plates 33 of the second structural member 30 are accommodated in the second receiving groove 437.

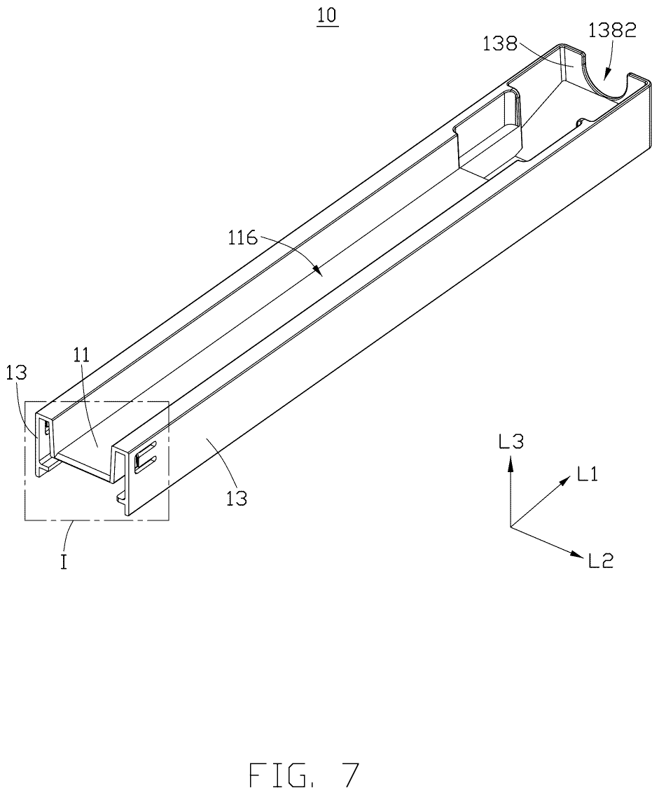

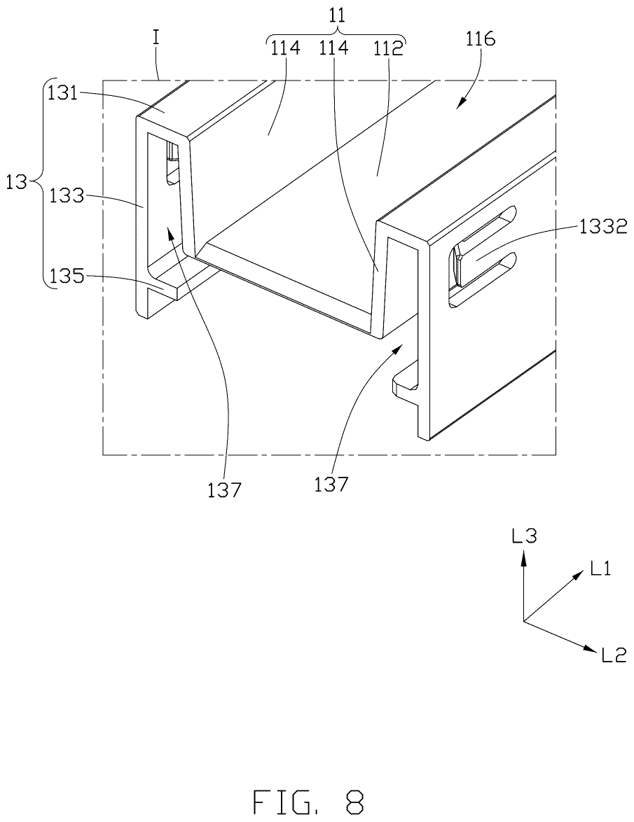

Referring to FIGS. 7 and 8, each first latching portion 13 may further include a first supporting plate 135 extending along the first direction L1. The first supporting plate 135 is connected to the second side plate 133, and the first connecting plate 131 and the first supporting plate 135 are disposed on the side of the second side plate 133 facing the first side plates 114. The first supporting plate 135 is spaced apart from the first connecting plate 131. The first supporting plate 135 can support the connecting member 40 and prevent the connecting member 40 from separating from the first structural member 10 along the third direction L3.

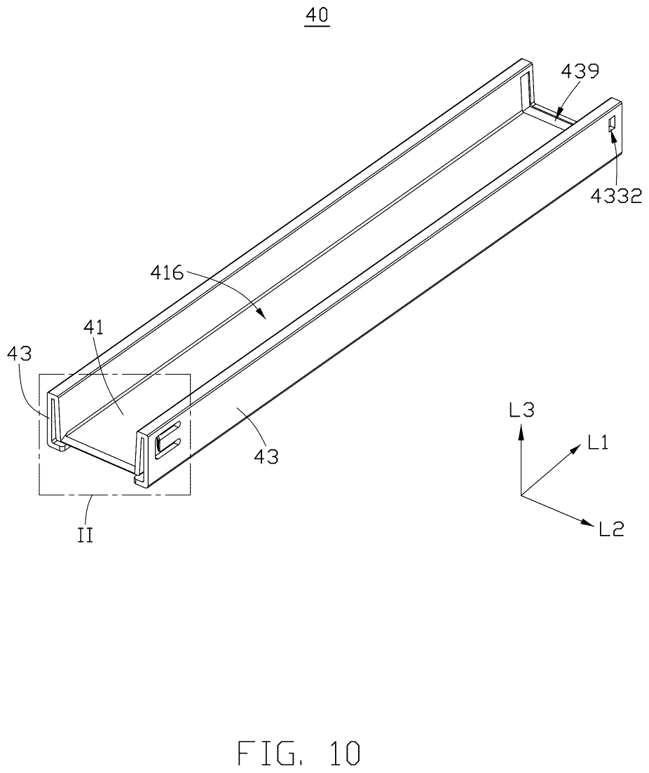

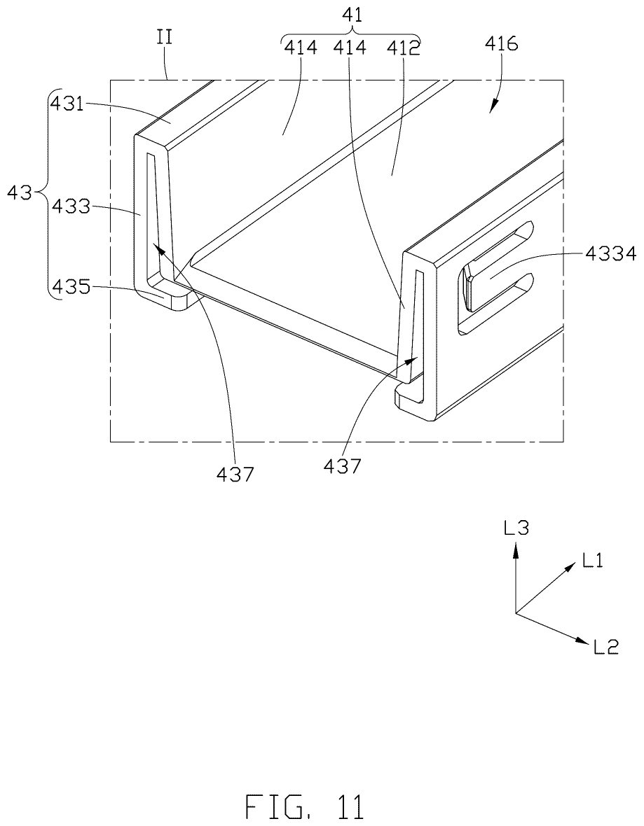

Referring to FIGS. 10 and 11, each second latching portion 43 may further include a second supporting plate 435 extending along the first direction L1. The second supporting plate 435 is connected to the fifth side plate 433, and the second connecting plate 431 and the second supporting plate 435 are disposed on a side of the fifth side plate 433 facing the fourth side plate 414. The second supporting plate 435 is spaced apart from the second connecting plate 431. The second supporting plate 435 can support the second structural member 30 and prevent the second structural member 30 from separating from the connecting member 40 along the third direction L3.

One end of the first structural member 10 is fixed to the housing 210. The first structural member 10 is closer to the liquid cooler 230 relative to the second structural member 30. One end of the pipeline 240 is connected to the liquid cooler 230, and another end of the pipeline 240 extends through the first structural member 10, the connecting member 40, and the second structural member 30. The another end of the pipeline 240 is accommodated in the first structural member 10, the connecting member 40, and the second structural member 30.

Referring again to FIGS. 7 and 8, the first structural member 10 may further include an end plate 138. The end plate 138 is connected to the first bottom plate 112 and the two first side plates 114. The end plate 138 is disposed on the end of the first structural member 10 closer to the liquid cooler 230. The end plate 138 defines a through hole 1382. The through hole 1382 extends through the end plate 138 along the first direction L1. The pipeline 240 can extend through the hole 1382.

Referring to FIGS. 7, 8, 10, and 11, the first structural member 10 may further include a first latch 1332. The connecting member 40 defines a first clamping slot 4332, and the first latch 1332 can be latched in the first clamping slot 4332. In the embodiment, the first latch 1332 is disposed on the second side plate 133, and a surface of the first latch 1332 facing the first receiving groove 137 protrudes into the first receiving groove 137. The first clamping slot 4332 is defined on the fifth side plate 433. When the first structural member 10 and the connecting member 40 are in the extended state, the first latch 1332 is disposed on the end of the first structural member 10 closer to the connecting member 40, and the first clamping slot 4332 is defined at the end of the connecting member 40 closer to the first structural member 10. When the connecting member 40 and the first structural member 10 are extended to a certain degree, the first latch 1332 latches into the first clamping slot 4332. That is, cooperation between the first latch 1332 and the first clamping slot 4332 limits a maximum extending distance between the connecting member 40 and the first structural member 10.

In other embodiments, the first latch 1332 may be disposed on the first side plate 114, and the first clamping slot 4332 may be defined on the fourth side plate 414. Alternatively, the first latch 1332 may be disposed on the connecting member 40, and the first clamping slot 4332 may be defined on the first structural member 10, as long as the first structural member 10 and the connecting member 40 can be latched.

Referring to FIGS. 9, 10, and 11, the connecting member 40 may further include a second latch 4334, and the second structural member 30 defines a second clamping slot 333. The second latch 4334 can be latched in the second clamping slot 333. In the embodiment, the second latch 4334 is disposed on the fifth side plate 433, and a surface of the second latch 4334 facing the second receiving groove 437 protrudes into the second receiving groove 437. The second clamping slot 333 is defined on the third side plate 33.

When the connecting member 40 and the second structural member 30 are in the extended state, the second latch 4334 is disposed on the end of the connecting member 40 closer to the second structural member 30, and the second clamping slot 333 is defined on the end of the second structural member 30 closer to the connecting member 40. When the second structural member 30 and the connecting member 40 are extended to certain degree, the second latch 4334 latches into the second clamping slot 333. That is, the cooperation between the second latch 4334 and the second clamping slot 333 limits the maximum extending distance between the second structural member 30 and the connecting member 40.

When the first latch 1332 is latched into the first clamping slot 4332, and the second latch 4334 is latched into the second clamping slot 333, the liquid collecting assembly 100 is in the extended state.

In other embodiments, the second clamping slot 333 may be defined on the fourth side plate 414. Alternatively, the second latch 4334 may be disposed on the second structural member 30, and the second clamping slot 333 may be defined on the connecting member 40, as long as the connecting member 40 and the second structural member 30 can be latched at an appropriate position.

Referring to FIG. 4, the first structural member 10 may further include a first baffle plate 139. The first baffle plate 139 is disposed on the end of the first supporting plate 135 opposite to the second structural member 30. The first baffle plate 139 protrudes relative to the second supporting plate 435 along the third direction L3. When the first structural member 10 and the connecting member 40 are retracted to a certain degree, the first baffle plate 139 abuts against the end of the connecting member 40. That is, the first baffle plate 139 can limit the maximum retracting distance between the first structural member 10 and the connecting member 40.

Referring to FIG. 9, the second structural member 30 may further include a second baffle plate 39. The second baffle plate 39 is disposed om the end of the third side plate 33 opposite to the first structural member 10. The second baffle plate 39 protrudes relative to the third side plate 33 along the second direction L2. When the second structural member 30 and the connecting member 40 are retracted to a certain degree, the second baffle plate 39 abuts against the end of the connecting member 40. That is, the second baffle plate 39 can limit the maximum retracting distance between the second structural member 30 and the connecting member 40.

When the first baffle plate 139 abuts against the end of the connecting member 40, and the second baffle plate 39 abuts against the end of the connecting member 40, the liquid collecting assembly 100 is in the fully retracted state.

Referring to FIG. 6, the liquid collecting assembly 100 may further include a first sealing member 51. The first sealing member 51 is disposed between the first structural member 10 and the connecting member 40. The end of the second receiving portion 41 of the connecting member 40 closer to the first structural member 10 defines a first groove 439. The first groove 439 is defined at the surfaces of the first bottom plate 112 and the two first side plates 114. A cross-sectional view of the first groove 439 perpendicular to the third direction L3 is generally C-shaped. The first sealing member 51 is accommodated in the first groove 439, and a surface of the first sealing member 51 facing away from the connecting member 40 is in contact with a surface of the first receiving portion 11 of the first structural member 10. The first sealing member 51 can seal the first structural member 10 and the connecting member 40, thereby preventing leakage of the working medium between the first structural member 10 and the connecting member 40.

The liquid collecting assembly 100 may further include a second sealing member 52. The second sealing member 52 is disposed between the connecting member 40 and the second structural member 30. The end of the second structural member 30 closer to the connecting member 40 defines a second groove 37. The second groove 37 is defined at the surfaces of the second bottom plate 31 and the two second sidewalls 214. A cross-sectional view of the second groove 37 perpendicular to the third direction L3 is generally C-shaped. The second sealing member 52 is accommodated in the second groove 37, and a surface of the second sealing member 52 facing away from the second structural member 30 is in contact with a surface of the second receiving portion 41 of the connecting member 40. The second sealing member 52 can serve the connecting member 40 and the second structural member 30, thereby preventing leakage of the working medium between the connecting member 40 and the second structural member 30.

In some embodiments, the connecting member 40 can be omitted. That is, the liquid collecting assembly 100 can include the first structural member 10 and the second structural member 30 slidably connected to the first structural member 10. The first structural member 10 and the second structural member 30 can extend or retract along the first direction L1. When the liquid collecting assembly 100 is in the extended state, at least a portion of the second structural member 30 protrudes from the end of the first structural member 10, and the overall length of the liquid collecting assembly 100 along the first direction L1 is approximately the sum of the length of the first structural member 10 and the length of the second structural member 30. When the liquid collecting assembly 100 is in the retracted state, at least a portion of the second structural member 30 is accommodated in the first structural member 10, and the overall length of the liquid collecting assembly 100 along the first direction L1 is approximately the length of the first structural member 10.

In other embodiments, when the liquid collecting assembly 100 includes a plurality of connecting members 40, two adjacent connecting members 40 can be nested with each other.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A liquid collecting assembly comprising:
a first structural member comprising a first receiving portion and a first latching portion, the first receiving portion defining a first through slot, a first receiving groove formed between the first latching portion and the first receiving portion; and
a second structural member defining a second through slot, the first structural member slidably connected to the second structural member, the first receiving portion configured to accommodate in the second through slot, and the second structural member configured to accommodate in the first receiving groove.

2. The liquid collecting assembly of claim 1, wherein the first receiving portion comprises a first bottom plate and two first side plates, the two first side plates are disposed on two sides of the first bottom plate, the first bottom plate and the two first side plates cooperatively form the first through slot;
the first structural member further comprises two first latching portions, each of the two first latching portions comprises a first connecting plate and a second side plate, the first connecting plate is connected to one of the two first side plates and the second side plate, one of the two first side plates is spaced apart from the second side plate; and one of the two first side plates, the first connecting plate, and the second side plate cooperatively form the first receiving groove.

3. The liquid collecting assembly of claim 2, wherein each of the two first latching portions further comprises a first supporting plate connected to the second side plate, the first connecting plate and the first supporting plate are disposed on a side of the second side plate facing one of the two first side plates, and the first supporting plate is spaced apart from the first connecting plate.

4. The liquid collecting assembly of claim 1, wherein second structural member comprises a second bottom plate and two third side plates, the two third side plates are disposed on two sides of the second bottom plate, and the second bottom plate and the two third side plates cooperatively form the second through slot.

5. The liquid collecting assembly of claim 2, wherein second structural member comprises a second bottom plate and two third side plates, the two third side plates are disposed on two sides of the second bottom plate, and the second bottom plate and the two third side plates cooperatively form the second through slot.

6. The liquid collecting assembly of claim 1, further comprising a connecting member, wherein each of the connecting member comprises a second receiving portion and two second latching portions, the second receiving portion defines a third through slot, one of the two second latching portions and the second receiving portion cooperatively form the third through slot;
the first structural member is slidably connected to the connecting member, the connecting member is slidably connected to the second structural member, the first receiving portion is configured to accommodate in the third through slot, one of the two second latching portions are configured to accommodate in the first through slot, the second receiving portion is configured to accommodate in the second through slot, and the second structural member is configured to accommodate in the second receiving groove;
when the liquid collecting assembly is in an extended state, at least a portion of the second structural member protrudes from an end of the connecting member, and at least a portion of the connecting member protrudes from an end of the first structural member;
when the liquid collecting assembly is in a retracted state, at least a portion of the second structural member is accommodated in the connecting member, and at least a portion of the connecting member is accommodated in the first structural member.

7. The liquid collecting assembly of claim 6, wherein the second receiving portion comprises a third bottom plate and two fourth side plates, the two fourth side plates are disposed on two sides of the third bottom plate, the third bottom plate and the two fourth side plates cooperatively form the third through slot;
each of the two second latching portions comprises a second connecting plate and a fifth side plate, the second connecting plate is connected to one of the two fourth side plates and the fifth side plate, the fourth side plate is spaced apart from the fifth side plate;
one of the two fourth side plates, the second connecting plate, and the fifth side plate cooperatively form the second receiving groove.

8. The liquid collecting assembly of claim 7, wherein each of the two second latching portions further comprises a second supporting plate, the second supporting plate is connected to the fifth side plate, the second connecting plate and the second supporting plate are disposed on a side of the fifth side plate facing one of the two fourth side plates, and the second supporting plate is spaced apart from the second connecting plate.

9. The liquid collecting assembly of claim 6, further comprising a first sealing member and a second sealing member, wherein the connecting member defines a first groove, the first sealing member is accommodated in the first groove and in contact with the first receiving portion;
the second structural member defines a second groove, and the second sealing member is accommodated in the second groove and in contact with the second receiving portion.

10. The liquid collecting assembly of claim 6, wherein one of the first structural member and the connecting member further comprises a first latch, another of the first structural member and the connecting member further comprises a first clamping slot, when the first structural member and the connecting member are in the extended state, and the first latch is latched in the first clamping slot;
one of the connecting member and the second structural member further comprises a second latch, another of the connecting member and the second structural member further comprises a second clamping slot, when the connecting member and the second structural member are in the extended state, and the second latch is latched in the second clamping slot.

11. A terminal device comprising:
a liquid cooler;
a pipeline; and
a liquid collecting assembly comprising:
a first structural member comprising a first receiving portion and a first latching portion, the first receiving portion defining a first through slot, a first receiving groove formed between the first latching portion and the first receiving portion; and
a second structural member defining a second through slot, the first structural member slidably connected to the second structural member, the first receiving portion configured to accommodate in the second through slot, and the second structural member configured to accommodate in the first receiving groove;
wherein one end of the pipeline is connected to the liquid cooler, and another end of the pipeline extends through the first receiving groove and the second receiving groove.

12. The terminal device of claim 11, wherein the first receiving portion comprises a first bottom plate and two first side plates, the two first side plates are disposed on two sides of the first bottom plate, the first bottom plate and the two first side plates cooperatively form the first through slot;
the first structural member further comprises two first latching portions, each of the two first latching portions comprises a first connecting plate and a second side plate, the first connecting plate is connected to one of the two first side plates and the second side plate, one of the two first side plates is spaced apart from the second side plate; and one of the two first side plates, the first connecting plate, and the second side plate cooperatively form the first receiving groove.

13. The terminal device of claim 12, wherein each of the two first latching portions further comprises a first supporting plate connected to the second side plate, the first connecting plate and the first supporting plate are disposed on a side of the second side plate facing one of the two first side plates, and the first supporting plate is spaced apart from the first connecting plate.

14. The terminal device of claim 11, wherein second structural member comprises a second bottom plate and two third side plates, the two third side plates are disposed on two sides of the second bottom plate, and the second bottom plate and the two third side plates cooperatively form the second through slot.

15. The terminal device of claim 12, wherein second structural member comprises a second bottom plate and two third side plates, the two third side plates are disposed on two sides of the second bottom plate, and the second bottom plate and the two third side plates cooperatively form the second through slot.

16. The terminal device of claim 11, wherein the liquid collecting assembly further comprises a connecting member, each of the connecting member comprises a second receiving portion and two second latching portions, the second receiving portion defines a third through slot, one of the two second latching portions and the second receiving portion cooperatively form the third through slot;
the first structural member is slidably connected to the connecting member, the connecting member is slidably connected to the second structural member, the first receiving portion is configured to accommodate in the third through slot, one of the two second latching portions are configured to accommodate in the first through slot, the second receiving portion is configured to accommodate in the second through slot, and the second structural member is configured to accommodate in the second receiving groove;
when the liquid collecting assembly is in an extended state, at least a portion of the second structural member protrudes from an end of the connecting member, and at least a portion of the connecting member protrudes from an end of the first structural member;
when the liquid collecting assembly is in a retracted state, at least a portion of the second structural member is accommodated in the connecting member, and at least a portion of the connecting member is accommodated in the first structural member.

17. The terminal device of claim 16, wherein the second receiving portion comprises a third bottom plate and two fourth side plates, the two fourth side plates are disposed on two sides of the third bottom plate, the third bottom plate and the two fourth side plates cooperatively form the third through slot;
each of the two second latching portions comprises a second connecting plate and a fifth side plate, the second connecting plate is connected to one of the two fourth side plates and the fifth side plate, the fourth side plate is spaced apart from the fifth side plate;
one of the two fourth side plates, the second connecting plate, and the fifth side plate cooperatively form the second receiving groove.

18. The terminal device of claim 17, wherein each of the two second latching portions further comprises a second supporting plate, the second supporting plate is connected to the fifth side plate, the second connecting plate and the second supporting plate are disposed on a side of the fifth side plate facing one of the two fourth side plates, and the second supporting plate is spaced apart from the second connecting plate.

19. The terminal device of claim 16, wherein the liquid collecting assembly further comprises a first sealing member and a second sealing member, the connecting member defines a first groove, the first sealing member is accommodated in the first groove and in contact with the first receiving portion;
the second structural member defines a second groove, and the second sealing member is accommodated in the second groove and in contact with the second receiving portion.

20. The terminal device of claim 16, wherein one of the first structural member and the connecting member further comprises a first latch, another of the first structural member and the connecting member further comprises a first clamping slot, when the first structural member and the connecting member are in the extended state, and the first latch is latched in the first clamping slot;
one of the connecting member and the second structural member further comprises a second latch, another of the connecting member and the second structural member further comprises a second clamping slot, when the connecting member and the second structural member are in the extended state, and the second latch is latched in the second clamping slot.
